(19) United States
(12) Patent Application Publication
(10) Pub. No.: US 2025/0221124 A1
(43) Pub. Date: Jul. 3, 2025

(54) DISPLAY APPARATUS

(71) Applicant: LG Display Co., Ltd., Seoul (KR)

(72) Inventors: AhnKi KIM, Paju-si (KR); EunJi PARK, Paju-si (KR); KyungYun KANG, Paju-si (KR); Hyeonjeong SHIN, Paju-si (KR); Junho NAM, Paju-si (KR)

(21) Appl. No.: 18/786,111

(22) Filed: Jul. 26, 2024

(30) Foreign Application Priority Data
Dec. 29, 2023 (KR) 10-2023-0197915

(51) Int. Cl. H01L 27/15; H01L 33/58

(52) U.S. Cl. CPC H10H 29/142; H10H 20/855; H10H 20/872

(57) ABSTRACT

A display apparatus is disclosed. The display apparatus includes a sub-pixel having a light emitting area. The sub-pixel includes a low-reflection layer disposed in the light emitting area. The low-reflection layer includes a first layer and a second layer disposed on the first layer. The second layer contains a low-resistance metal. The first layer includes a metal oxide containing an element M, and the element M includes a group 6B element.

### CROSS-REFERENCE TO RELATED APPLICATIONS

This application claims the benefit of priority of the Korean Patent Application No. 10-2023-0197915 filed on Dec. 29, 2023, which is hereby incorporated by reference as if fully set forth herein.

### BACKGROUND

### Technical Field

The present disclosure relates to a display apparatus.

### Description of the Related Art

As an information society develops, demands for display apparatus for displaying images is increasing in various forms. Accordingly, in recent years, various display apparatus such as a liquid crystal display (LCD), a plasma display (PDP), and an electroluminescence display (ELD) have been used. In addition, the electroluminescence display apparatus may include a display apparatus such as an organic light emitting display (OLED) and a quantum dot light emitting display (QLED).

Among the display apparatus, the electroluminescent display apparatus is a self-luminous type, and has advantages such as superior viewing angle and contrast ratio compared to liquid crystal display (LCD), light weight and thinness are possible because a separate backlight is not required, and power consumption is advantageous. In addition, the electroluminescent display apparatus has the advantage of being able to drive a DC low voltage, a fast response speed, and particularly low manufacturing cost.

On the other hand, when the electroluminescent display apparatus is configured in a so-called top emission method in which the emitted light is emitted upward, an anode composed of a five-layer film may be initiated to reduce the reflectance due to external light. For example, the anode may be formed in a structure in which a transparent conductive layer made of a transparent conductive material such as indium-Tin-oxide (ITO) or indium-zinc-oxide (IZO) and a metal layer made of a metal such as molybdenum (Mo) or titanium (Ti) are alternately stacked. In this case, the light introduced from the outside is reflected by a plurality of metal layers inside the anode, respectively, and thus interference occurs, so that the light introduced from the outside is extinguished and the reflectance due to external light may be reduced.

However, when the light emitted from the light emitting layer travels in the lower direction of the electroluminescent display apparatus, research is continuously being conducted to reduce the reflectance of external light while improving light efficiency.

### BRIEF SUMMARY

An embodiment of the present disclosure is to provide a display apparatus in which a reflectance of external light is reduced and light efficiency is improved by forming a low-reflection layer in a light emitting region.

In addition to the technical benefits of the present disclosure as mentioned above, additional benefits and features of the present disclosure will be clearly understood by those skilled in the art from the following description of the present disclosure.

In accordance with an aspect of the present disclosure, the above and other benefits can be accomplished by the provision of a display apparatus includes a sub-pixel having a light emitting area, and the sub-pixel includes a low-reflection layer disposed in the light emitting area, and the low-reflection layer includes a first layer and a second layer disposed on the first layer and containing a low-resistance metal, and the first layer includes a metal oxide (MOx) containing an element M, and the element M includes a group 6B element.

The low-reflection layer may have two or more low-reflection patterns, and the two or more low-reflection patterns may be spaced apart from each other in a first direction and disposed side by side.

The group 6B element may include at least one of chromium (Cr), molybdenum (Mo), and tungsten (W), and the low resistance metal may include at least one of Cu, Ag, Al, Mo, and Ti.

A first insulating layer on the low-reflective layer, a second insulating layer on the first insulating layer, a planarization layer on the second insulating layer, and a light emitting element layer on the planarization layer may be included.

The low-reflective layer may have an area ratio of 5 to 15% based on the total area of the light emitting area in which the low-reflective layer is disposed in a plan view.

The planarization layer may include a low refractive layer on the second insulating layer, and a high refractive layer disposed on the low refractive layer and having a lens shape.

The first insulating layer may be disposed on the second layer in the form of an island. An interface having a taper may be formed between the first insulating layer and the second insulating layer.

A plurality of bead particles dispersed in the planarization layer may be further included.

The plurality of bead particles may include metal oxide.

A light-absorbing layer; and a substrate on the light-absorbing layer are further included, and the low-reflective layer may be disposed on the substrate.

Each of the two or more low-reflection patterns may have a width of 3 μm to 5 μm in a plan view.

Each of the two or more low-reflection patterns may be disposed to be spaced apart from each other at intervals of 5 μm or more.

A reference line extending in a first direction and a reference voltage applied thereto; and a data line extending in the first direction and a data voltage applied thereto, and the low reflection layer may be connected to the reference line.

The low-reflection layer may be disposed to be spaced apart from the data line.

The low-reflective layer may have a mesh shape in a plan view.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a diagram illustrating a display apparatus according to an embodiment of the present disclosure.

FIG. 2 is a plan view illustrating a plane structure of one subpixel of FIG. 1.

FIG. 3 is a cross-sectional view taken along line I-I′ of FIG. 2.

FIG. 4 is a cross-sectional view taken along line II-II′ of FIG. 2.

FIG. 5 is a cross-sectional view of a subpixel according to another embodiment of the present disclosure.

FIG. 6 is a cross-sectional view of a subpixel according to another embodiment of the present disclosure.

FIG. 7 is a cross-sectional view of a subpixel according to another embodiment of the present disclosure.

FIG. 8 is a cross-sectional view of a subpixel according to another embodiment of the present disclosure.

FIG. 9A is a diagram illustrating a mechanism of external light reflection.

FIG. 9B is a diagram illustrating a mechanism of internal light emission.

FIG. 10 is a plan view of a subpixel according to another embodiment.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle, and a number of elements disclosed in the drawings for describing embodiments of the present disclosure are merely an example and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

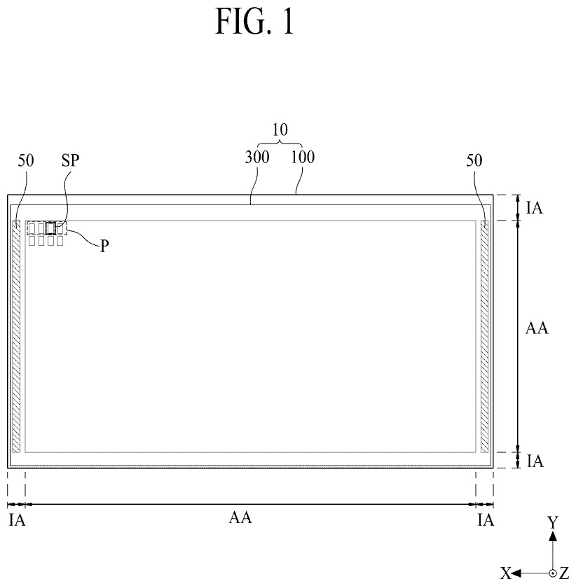

FIG. 1 is a diagram illustrating a display apparatus according to an embodiment of the present disclosure.

Referring to FIG. 1, a display apparatus according to an embodiment of the present specification may include a display panel 10 including a substrate 100 and a counter substrate 300 bonded to each other.

The substrate 100 includes a thin film transistor and may be a transparent glass substrate or a transparent plastic substrate. The substrate 100 may include a display area AA and a non-display area IA.

The display area AA is an area in which an image is displayed, and may be a pixel array area, an active area, a pixel array unit, a display unit, or a screen. The display area AA may include a plurality of pixels P. The plurality of pixels P may be unit areas in which actual light is emitted.

The non-display area IA is an area in which no image is displayed, and may be a peripheral circuit area, a signal supply area, an inactive area, or a bezel area. The non-display area IA may be configured to surround the display area AA. The display panel 10 or the substrate 100 may further include a peripheral circuit unit 50 disposed in the non-display area IA.

The counter substrate 300 may be bonded to face the substrate 100 through an adhesive member (or a transparent adhesive), or may be disposed in a manner in which an organic material or an inorganic material is stacked on the substrate 100. The counter substrate 300 may be an upper substrate, a second substrate, or an encapsulation substrate, and may correspond to encapsulating the substrate 100.

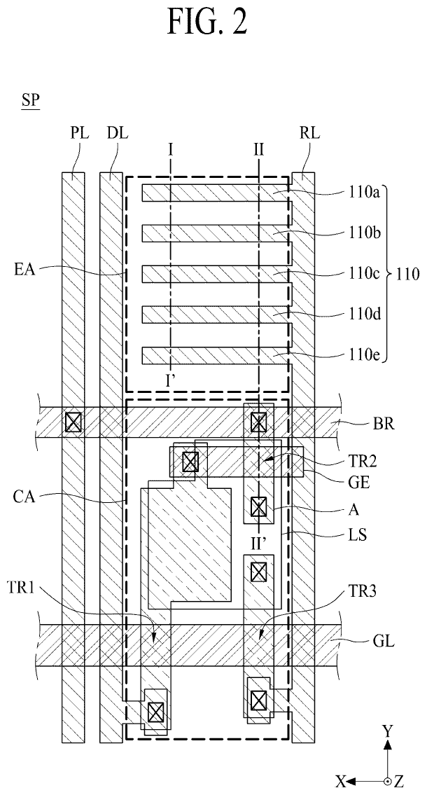

FIG. 2 is a plan view illustrating a plane structure of one subpixel of FIG. 1.

Referring to FIGS. 1 and 2, the display apparatus according to an embodiment of the present disclosure may include a plurality of unit pixels P in which one unit pixel P is formed of a plurality of subpixels SP in the display area AA.

One sub-pixel SP may include a light emitting area EA and a circuit area CA. The circuit area CA may be spatially separated from the light emitting area EA in the sub-pixel SP. The light emitting area EA is an area defined by being opened by the bank B in the sub-pixel SP. The circuit area CA may be a non-emission area or a non-opening area.

One unit pixel P may include four sub-pixels SP. The sub-pixel SP may include a red pixel, a white pixel, a blue pixel, and a green pixel. A gate line GL may be disposed to extend while crossing between the light emitting area EA and the circuit area CA of the sub-pixel SP. Between each sub-pixel SP, a plurality of data lines DL or reference lines RL are disposed to extend while crossing the light emitting area EA and the adjacent light emitting area EA or between the circuit area CA and the adjacent circuit area CA.

Specifically, referring to FIG. 2, the data line DL, the power line PL, and the reference line RL extend in the first direction Y, respectively, and the gate line GL, and bridge BR are disposed to extend in the second direction X perpendicular to the first direction Y.

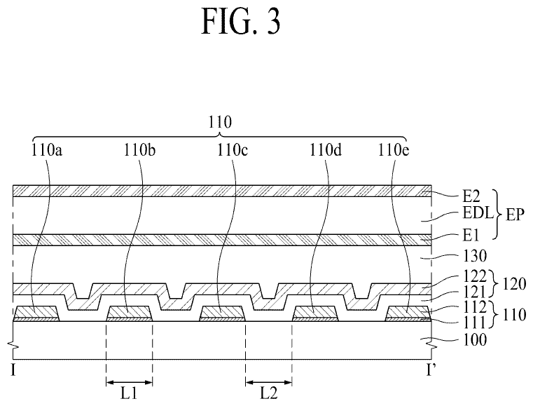

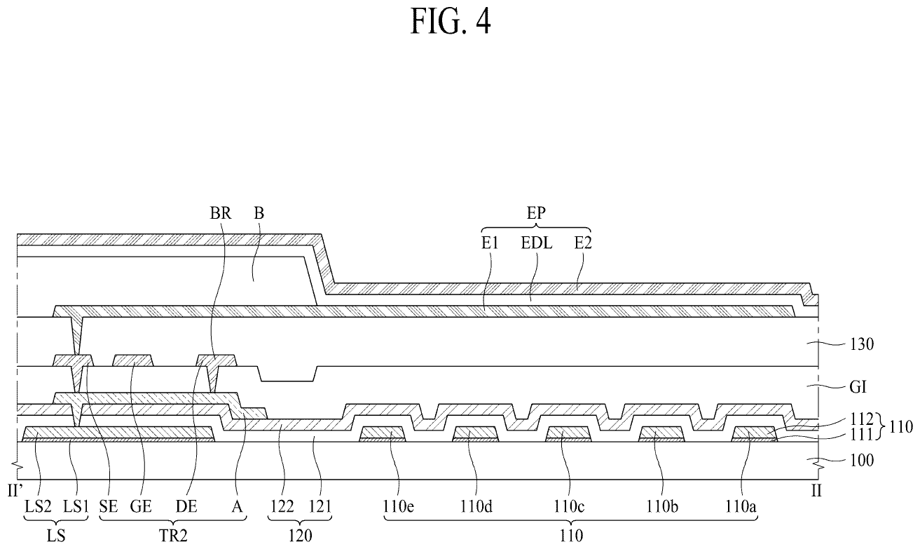

FIG. 3 is a cross-sectional view taken along line I-I′ of FIG. 2, and FIG. 4 is a cross-sectional view taken along line II-II′ of FIG. 2.

Referring to FIGS. 3 and 4, a display apparatus according to an embodiment of the present disclosure may include a substrate 100, a low reflection layer 110, an insulating layer 120, a planarization layer 130, a driving thin film transistor TR2, and a light emitting element layer EP. The light emitting element layer EP is driven by the driving thin film transistor TR2 disposed between the substrate 100 and the planarization layer 130 in the circuit area CA.

The display apparatus according to an embodiment of the present disclosure may be configured in a bottom emission method. Therefore, a transparent material may be used as the material of the substrate 100.

According to an embodiment of the present disclosure, the sub-pixel SP may include a low-reflection layer 110 disposed in the light emitting area EA. Specifically, referring to FIG. 3, the low-reflection layer 110 is disposed on the substrate 100.

The low reflection layer 110 includes a first layer 111 and a second layer 112 on the first layer 111. In this case, the first layer 111 may include a metal oxide (MOx) containing an element M, and the second layer 112 may include a low resistance metal. In this case, the element M may include a group 6B element. For example, the group 6B element may include at least one of chromium (Cr), molybdenum (Mo), and tungsten (W), and the low resistance metal may include at least one of Cu, Ag, Al, Mo, and Ti.

When the first layer 111 of the low-reflection layer 110 includes a metal oxide (MOx) containing an element M and the second layer 112 includes a low-resistance metal, the first layer 111 may reflect a part of light incident from the outside, and transmit or absorb the remaining part of the light. In addition, the remaining light that has passed through transmission or absorption in the first layer 111 may be reflected from the surface of the second layer 112 of the low-reflection layer 110. Accordingly, the light reflected from the first layer 111 and the second layer 112 meet on the surface of the first layer 111 in a state of being in opposite phases to cause destructive interference. As a result, it is possible to reduce or prevent an increase in reflectance due to external light in the display apparatus.

According to an embodiment of the present disclosure, the low-reflection layer 110 has two or more low-reflection patterns 110a, 110b, 110c, 110d, and 110e, and the two or more low-reflection patterns 110a, 110b, 110c, 110d, and 110e may be spaced apart from each other and disposed side by side along the first direction Y.

In FIG. 2, the low-reflection layer 110 disposed in the light emitting area EA has a structure in which five low-reflection patterns 110a, 110b, 110c, 110d, and 110e are disposed. In this case, each of the low-reflection patterns 110a, 110b, 110c, 110d, and 110e is elongated along the second direction X, and is spaced apart from each other and arranged in parallel along the first direction Y.

More specifically, the low-reflection layer 110 may have an area ratio of 5 to 15% of the total area of the light emitting area EA in which the low-reflection layer 110 is disposed in a plan view.

On the other hand, when the low-reflective layer 110 has an area ratio of 5% or less of the total area of the light emitting area EA, the low-reflective layer 110 is disposed excessively small in the light emitting area EA. Therefore, it may be difficult to achieve the desired reduction in the reflectance of external light in the present disclosure.

In addition, if the low-reflection layer (110) has an area ratio exceeding 15% of the total area of the light emitting area (EA), the low-reflection layer (110) is excessively arranged in the light emitting area (EA) to achieve the purpose of reducing the reflectance of external light, but the light efficiency of the display apparatus decreases.

Therefore, in order to reduce the reflectance of external light and improve the light efficiency of the display apparatus, the low-reflection layer 110 needs to have an area ratio of 5 to 15% of the total area of the light emitting area (EA).

In addition, according to one embodiment of the present disclosure, the low-reflection layer 110 has two or more low-reflection patterns 110a, 110b, 110c, 110d, and 110e, and the low-reflection patterns 110a, 110b, 110c, 110d, and 110e may each have a width (L1) of 3 μm to 5 μm in a plane.

On the other hand, it may be difficult for the low-reflection patterns 110a, 110b, 110c, 110d, and 110e to have a width (L1) of less than 3 μm in a plane.

In addition, if the low-reflection patterns (110a, 110b, 110c, 110d, and 110e) each have a width (L1) exceeding 5 μm in a plane, the low-reflection layer (110) is excessively arranged in the light emitting area (EA) to achieve the purpose of reducing the reflectance of external light, but the light efficiency of the display apparatus decreases.

Therefore, for actual process margin and light efficiency, each of the low-reflection patterns 110a, 110b, 110c, 110d, and 110e needs to have a width (L1) of 3 μm to 5 μm in a plane.

In addition, according to one embodiment of the present disclosure, the low-reflection layer 110 has two or more low-reflection patterns 110a, 110b, 110c, 110d, and 110e, and the low-reflection patterns 110a, 110b, 110c, 110d, and 110e may be arranged at intervals (L2) of 5 μm or more in a plane.

On the other hand, when the low-reflection patterns (110a, 110b, 110c, 110d, 110e) are spaced apart on the plane at an interval (L2) of less than 5 μm, when the light emitted from the light-emitting element layer is emitted between the low-reflection patterns (110a, 110b, 110c, 110d, and 110e), an interval between the low reflection patterns 110a, 110b, 110c, 110d, and 110e is very narrow, and thus light extraction may be difficult.

Although FIGS. 2 and 3 show a configuration having five low-reflection patterns 110a, 110b, 110c, 110d, and 110e, an embodiment of the present disclosure is not limited thereto, and the number may be less than five or more than five.

According to an embodiment of the present disclosure, the display apparatus includes a reference line RL and a data line DL. In this case, referring to FIG. 2, the reference line RL is extended in the first direction Y to apply a reference voltage, and the data line DL is extended in the first direction Y to apply a data voltage.

According to an embodiment of the present disclosure, the low reflection layer 110 may be connected to the reference line RL. Specifically, referring to FIG. 2, the low reflection layer 110 may be integrally formed with the reference line RL.

In general, an equal voltage is applied to the reference line RL. That is, when the low-reflection layer 110 is connected to the reference line RL and is integrally formed, there is an advantage of being formed by the same process, and at the same time, it is connected to a wiring to which a constant voltage is applied to stably form the low-reflection layer 110.

On the other hand, according to an embodiment of the present disclosure, the low-reflection layer 110 is not limited to being connected to the reference line RL, but may be connected to a wiring having an equal voltage (constant voltage).

In addition, the low-reflection layer 110 may be disposed to be spaced apart from the data line DL. When the low-reflection layer 110 contacts the data line DL, a problem of shorting may occur.

Referring to FIGS. 2 and 4, a light blocking layer LS is disposed in the circuit area CA. In detail, the light blocking layer LS disposed in the circuit area CA is disposed on the substrate 100, and is disposed on the same layer as the low reflection layer 110. In more detail, the light blocking layer LS overlaps at least a portion of the active layer A of the driving thin film transistor TR2.

The light blocking layer LS may be formed by the same process as the low-reflection layer 110, the first layer LS1 of the light blocking layer is disposed on the same layer as the first layer 111 of the low-reflection layer 110, and the second layer LS2 of the light blocking layer is disposed on the same layer as the second layer 112 of the low-reflection layer 110.

Referring to FIGS. 2 and 4, the display apparatus further includes an insulating layer 120. The insulating layer 120 is disposed over the entire light emitting area EA and the circuit area CA, and the insulating layer 120 is disposed on the low reflection layer 110 and the light blocking layer LS.

According to an embodiment of the present disclosure, the insulating layer 120 includes the first insulating layer 121 on the low reflection layer 110 and the second insulating layer 122 on the first insulating layer 121.

The insulating layer 120 may serve to block diffusion of a material contained in the substrate 100 into the thin film transistor during a high-temperature process during a thin film transistor manufacturing process or may also serve to prevent external moisture or humidity from penetrating toward the light emitting element layer EP. Optionally, the insulating layer 120 may be composed of a plurality of layers or may be omitted in some cases.

Referring to FIGS. 2 and 4, in the circuit area CA, a switching thin film transistor TR1, a driving thin film transistor TR2, and a sensing thin film transistor TR3 are disposed on a substrate 100. In the circuit area CA, a capacitor and a light blocking layer LS may be further disposed except for a thin film transistor.

The driving thin film transistor TR2 may include an active layer A, a gate electrode GE, a source electrode SE, and a drain electrode DE. Also, the driving thin film transistor TR2 may further include a gate insulating layer GI.

The active layer A may be formed of a semiconductor material based on any one of amorphous silicon, polycrystalline silicon, oxide, and organic material.

The gate electrode GE is disposed on the active layer A. The gate electrode GE is spaced apart from the active layer A and is disposed to at least partially overlap the active layer A.

The source electrode SE and the drain electrode DE are spaced apart from each other and are connected to the active layer A, respectively. Although FIG. 4 illustrates a structure in which the gate electrode GE, the source electrode SE, and the drain electrode DE are disposed on the same layer, an embodiment of the present disclosure is not limited thereto and may be disposed on different layers.

The driving thin film transistor TR2 may further include a gate insulating layer GI. The gate insulating layer GI is disposed between the active layer A and the gate electrode GE. Specifically, the gate insulating layer GI may be patterned to expose a portion of the active layer A, and may be formed on the entire surface of the circuit area CA and the light emitting area EA.

According to an embodiment of the present disclosure, the display apparatus may further include a planarization layer 130. The planarization layer 130 is disposed on the insulating layer 120, and more particularly, on the second insulating layer 122 of the insulating layer 120.

The planarization layer 130 may be formed of an organic layer such as an acrylic resin, an epoxy resin, a phenolic resin, a polyamide resin, a polyimide resin, or the like.

According to an embodiment of the present disclosure, the planarization layer 130 may be disposed over the entire light emitting area EA and the circuit area CA.

According to an embodiment of the present disclosure, the display apparatus may include a light emitting element layer EP. The light emitting element layer EP is driven by the driving thin film transistor TR2 disposed between the substrate 100 and the planarization layer 130 in the circuit area CA.

Referring to FIGS. 3 and 4, a bank B and a light emitting element layer EP consisting of a first electrode E1, a light emitting layer EDL, and a second electrode E2 are disposed on the planarization layer 130.

The first electrode E1 may be disposed on the planarization layer 130 and may be connected to the driving thin film transistor TR2. In detail, the first electrode E1 may be connected to the source electrode SE or the drain electrode DE of the driving thin film transistor TR2 through a contact hole (not shown) penetrating the planarization layer 130. Thus, the first electrode E1 may be electrically connected to the driving thin film transistor TR2.

The light emitting layer EDL may be disposed on the first electrode E1 to be in direct contact with the first electrode E1. The light emitting layer EDL may be disposed (or deposited) on the first electrode E1 to have a relatively greater thickness than the first electrode E1, and thus may have a surface shape along the surface shape of the first electrode E1.

The emission layer EDL includes two or more emission layers for emitting white light. For example, the emission layer EDL may include a first emission layer and a second emission layer for emitting white light by mixing the first light and the second light. The first emission layer may include any one of a blue emission layer, a green emission layer, a red emission layer, a yellow emission layer, and a yellow-green emission layer to emit the first light. The second emission layer may include an emission layer for emitting second light from the light emitting element layer EP by mixing with the first light among the blue emission layer, the green emission layer, the red emission layer, the yellow emission layer, and the yellow-green emission layer. The emission layer EDL according to another embodiment may include any one of a blue emission layer, a green emission layer, and a red emission layer.

The second electrode E2 may be disposed on the light emitting layer EDL to be in direct contact with the light emitting layer EDL. The second electrode E2 may have a surface shape that directly follows the surface shape of the light emitting layer EDL.

The second electrode E2 may include a metal material having high reflectivity in order to reflect light emitted from the light emitting layer EDL and incident thereon toward the substrate 100. For example, the second electrode E2 may include a single-layered structure or a multilayer structure formed of any one material selected from aluminum (Al), silver (Ag), molybdenum (Mo), gold (Au), magnesium (Mg), calcium (Ca), or barium (Ba). The second electrode E2 may include an opaque conductive material having high reflectivity.

The bank B may be provided on the planarization layer 130. In addition, the bank B may be provided between the first electrodes EL. In addition, the bank B may cover an edge of each of the first electrodes E1 and may be formed such that a portion of each of the first electrodes E1 is exposed. Accordingly, the bank B may prevent a problem in which a current is concentrated at an end of each of the first electrodes E1 and thus luminous efficiency is deteriorated.

The bank B may define the light emitting area EA of each of the sub-pixels SP. The light emitting area EA of each of the sub-pixels SPs represents an area in which the first electrode E1, the light emitting layer EDL, and the second electrode E2 are sequentially stacked to emit light by combining holes from the first electrode E1 and electrons from the second electrode E2 with each other in the light emitting layer EDL. In this case, the area in which the bank B is formed does not emit light and thus becomes a non-emission area, and the area in which the bank B is not formed and the first electrode E1 is exposed may become the light emitting area EA.

The bank B may be formed of an organic layer such as an acrylic resin, an epoxy resin, a phenolic resin, a polyamide resin, a polyimide resin, or the like.

Although not shown in the drawings, according to an embodiment of the present disclosure, an encapsulation layer may be provided on the light emitting element layer EP. The encapsulation layer may be formed on the second electrode E2 to cover the second electrode E2. The encapsulation layer serves to prevent the penetration of oxygen or moisture into the light emitting layer EDL and the second electrode E2. To this end, the encapsulation layer may include at least one inorganic layer and at least one organic layer.

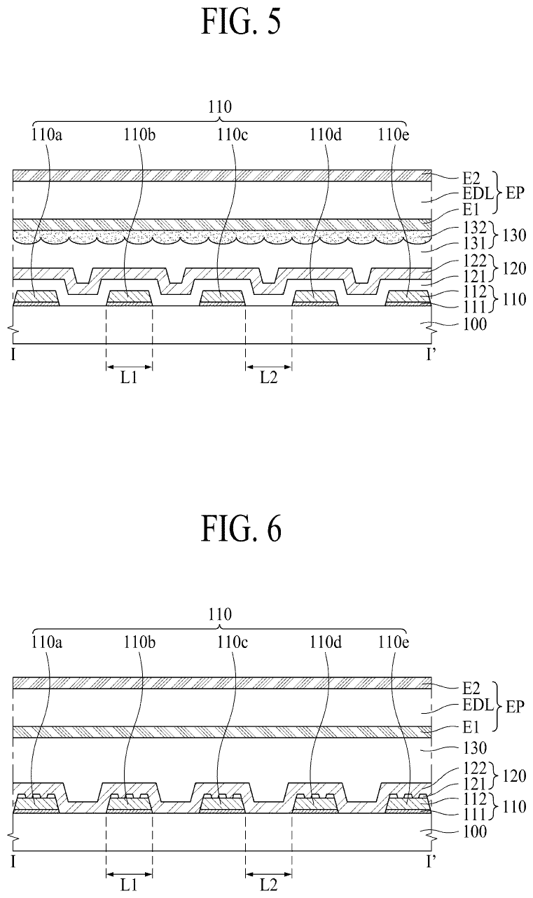

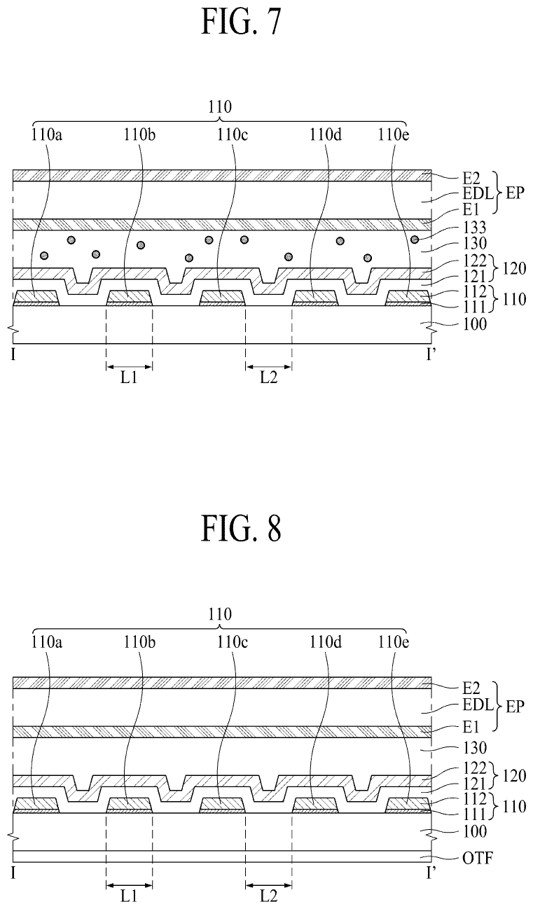

FIG. 5 is a cross-sectional view of a subpixel, according to another embodiment of the present disclosure. FIG. 6 is a cross-sectional view of a subpixel, according to another embodiment of the present disclosure. FIG. 7 is a cross-sectional view of a subpixel, according to another embodiment of the present disclosure. FIG. 8 is a cross-sectional view of a subpixel, according to another embodiment of the present disclosure.

Specifically, cross-sectional views of the subpixel SP according to FIGS. 5 to 8 correspond to the cross-sectional views shown in FIG. 3.

Referring to FIG. 5, the planarization layer 130 may include a low refractive layer 131 and a high refractive layer 132 on the low refractive layer 131.

Specifically, the planarization layer 130 may include a low refractive layer 131 on the second insulating layer 122 and a high refractive layer 132 disposed on the low refractive layer 131 and having a lens shape.

The low refractive layer 131 may be formed of a material having a first refractive index n1, and the high refractive layer 132 may be formed of a material having a second refractive index n2 different from the first refractive index n1. More specifically, the difference between the first refractive index n1 and the second refractive index n2 may be 0.05 to 0.40.

When the difference in the refractive index between the first refractive index n1 and the second refractive index n2 is 0.05 to 0.40, even if the light generated from the light emitting layer EDL is not extracted to the outside and is reflected by the second layer 112 of the low reflection layer 110, the path of light is converted by the low refractive layer 131 and the high refractive layer 132 of the planarization layer 130 to increase the efficiency of light extraction.

According to an embodiment of the present disclosure, the first insulating layer 121 of the insulating layer 120 may be disposed in the form of an island. Specifically, the first insulating layer 121 is disposed on the second layer 112 of the low reflection layer 110, and the second insulating layer 122 is disposed on the first insulating layer 121 disposed in the form of an island.

Referring to FIG. 6, when the first insulating layer 121 is disposed in the form of an island, there is an interface having a certain taper between the first insulating layer 121 and the second insulating layer 122. In this case, even if the light generated from the light emitting layer EDL is not extracted to the outside and is incident toward the low reflection layer 110, the path of light is converted at the interface between the first insulating layer 121 and the second insulating layer 122 disposed in the form of an island from the upper portion of the low reflection layer 110, thereby increasing the efficiency of light extraction.

Referring to FIG. 7, according to an embodiment of the present disclosure, the display apparatus may further include a plurality of bead particles 133 dispersed in the planarization layer 130.

In this case, by dispersing and arranging a plurality of bead particles 133 in the planarization layer 130, light emitted from the light emitting layer EDL can be prevented from being partially concentrated, thereby improving the efficiency of light extraction.

A plurality of bead particles 133 may be used alone or in a mixture of metal oxides such as SiO2, TiO2, Al2O3, B2O3, CaO, SnO, MgO, SrO, ZnO, ZrO2, Y2O3, and La2O3.

Referring to FIG. 8, according to an embodiment of the present disclosure, the display apparatus may further include a light absorbing layer OTF. The substrate 100 is disposed on the light absorbing layer OTF, and is disposed between the light absorbing layer OTF and the low reflection layer 110.

The light absorbing layer OTF may include a light absorbing material. For example, the light absorbing material may be a dye or pigment that absorbs visible light having a wavelength band of 380 nm to 780 nm. It is preferable that the light absorbing layer OTF has a light absorption rate of 50% or less (or a light transmittance of 50% or more) for visible light in a wavelength band of 380 nm to 780 nm. By adjusting the content of the light absorbing material of the light absorbing layer OTF, the reflectance of light incident on the light emitting area EA may be set to be 1.9 to 2.0%.

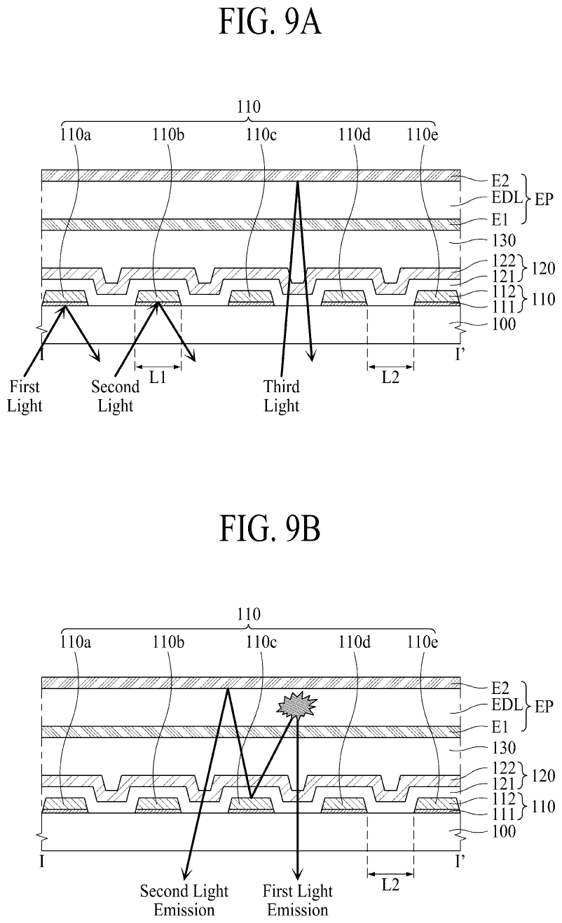

FIG. 9A is a diagram illustrating a mechanism of reflection of external light. FIG. 9B is a diagram illustrating a mechanism of internal light emission.

Referring to FIG. 9A, light incident from the outside (first light, second light, and third light) may be reflected from the first layer 111, the second layer 112, and the second electrode E2 of the low reflection layer 110.

Specifically, the first light incident from the outside is incident on the area where the low-reflection layer 110 is disposed, and a part of the first light incident is reflected from the first layer 111 of the low-reflection layer 110.

In addition, like the first light, the second light incident from the outside enters the area where the low-reflection layer 110 is placed, and a part of the incident second light passes through the first layer 111 and is reflected from the second layer 112 on the first layer 111.

Specifically, the light reflected from the first layer 111 and the second layer 112 causes destructive interference on the surface of the first layer 111 in a state of being in opposite phases to each other. As a result, an increase in reflectance with respect to external light in the display apparatus may be reduced or prevented.

The third light incident from the outside is incident on an area where the low-reflection layer 110 is not disposed, and the incident third light is reflected from the second electrode E2 of the light emitting element layer EP.

Referring to FIG. 9B, when the light emitting layer EDL emits light, it may proceed to an area where the low-reflection layer 110 is not disposed and be extracted, and may proceed to an area where the low-reflection layer 110 is disposed and may not be extracted.

Specifically, in the case of the first light emission, it shows that the light generated from the light emitting layer EDL of the light emitting element layer EP proceeds to the area where the low-reflection layer 110 is not disposed and is extracted.

In the case of the second light emission, light generated from the light emitting layer EDL of the light emitting element layer EP is reflected by the second layer 112 of the low reflection layer 110 so that the path of light is converted therein. Specifically, since the second layer 112 includes a low resistance metal, light generated from the light emitting layer EDL may be reflected with high efficiency when the light generated from the light emitting layer EDL travels to the second layer 112 of the low reflection layer 110.

FIG. 9B shows that light generated from the light emitting layer EDL of the light emitting element layer EP is reflected from the second layer 112 of the low-reflection layer 110 and reflected again by the second electrode E2 to proceed to an area where the low-reflection layer 110 is not disposed and extracted.

However, the optical path according to the present disclosure is not limited thereto, and light generated from the light emitting layer EDL of the light emitting element layer EP may be reflected twice or more from the second layer 112 of the low reflection layer 110, and as shown in FIGS. 5 to 7, the optical path may be converted by the internal structure to extract light to the outside.

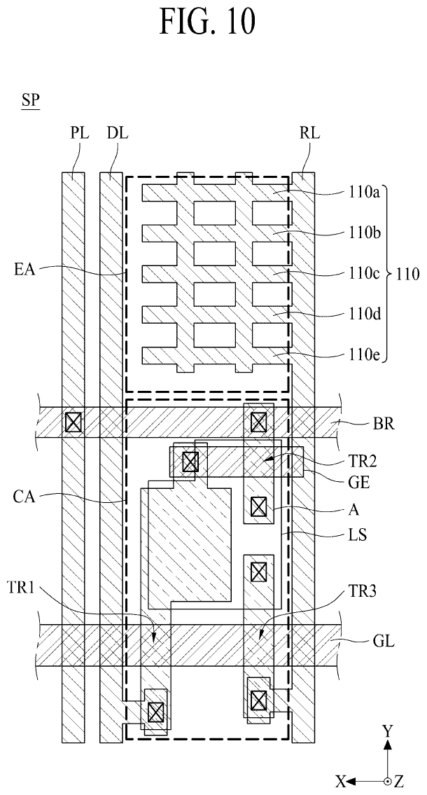

FIG. 10 is a plan view of a subpixel according to another embodiment.

According to an embodiment of the present disclosure, the low-reflection layer 110 may have a mesh shape in a plan view. In FIG. 10, the low-reflection layer 110 has a lattice shape arranged in the first direction Y and the second direction X.

According to the present disclosure, the following advantageous effects may be obtained.

In the display apparatus according to an embodiment of the present disclosure, by forming a low-reflective layer in a light emitting region, reflectance of external light may be reduced and light efficiency may be improved.

In addition to the above-mentioned effects, other features and advantages of the present disclosure may be described below, or may be clearly understood by those of ordinary skill in the art to which the present disclosure belongs from such techniques and descriptions.

In addition to the above-mentioned effects, other features and advantages of the present disclosure will be described below or clearly understood by those of ordinary skill in the art to which the present disclosure belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus includes:
a sub-pixel having a light emitting area, the sub-pixel including a low-reflection layer disposed in the light emitting area, the low-reflection layer including a first layer and a second layer disposed on the first layer,
wherein the second layer contains a low-resistance metal,
wherein the first layer includes a metal oxide containing an element M, and
wherein the element M includes a group 6B element.

2. The display apparatus of claim 1, wherein the low-reflection layer has two or more low-reflection patterns, and
wherein the two or more low-reflection patterns are spaced apart from each other in a first direction and disposed side by side.

3. The display apparatus of claim 1, wherein the group 6B element includes at least one of chromium (Cr), molybdenum (Mo), and tungsten (W).

4. The display apparatus of claim 1, wherein the low resistance metal includes at least one of copper (Cu), silver (Ag), aluminum (Al), molybdenum (Mo), and titanium (Ti).

5. The display apparatus of claim 1, further including a first insulating layer on the low-reflective layer;
a second insulating layer on the first insulating layer;
a planarization layer on the second insulating layer; and
a light emitting element layer on the planarization layer.

6. The display apparatus of claim 1, wherein the low-reflective layer has an area ratio of 5% to 15% based on a total area of the light emitting area in which the low-reflective layer is disposed in a plan view.

7. The display apparatus of claim 5, wherein the planarization layer includes:
a low refractive layer on the second insulating layer; and
a high refractive layer disposed on the low refractive layer and having a lens shape.

8. The display apparatus of claim 5, wherein the first insulating layer is disposed on the second layer in the form of an island.

9. The display apparatus of claim 8, wherein an interface having a taper is formed between the first insulating layer and the second insulating layer.

10. The display apparatus of claim 5, further including a plurality of bead particles dispersed in the planarization layer.

11. The display apparatus of claim 10, wherein the plurality of bead particles includes metal oxide.

12. The display apparatus of claim 1, further including:
a light-absorbing layer; and
a substrate on the light-absorbing layer; and
wherein the low-reflective layer is disposed on the substrate.

13. The display apparatus of claim 2, each of the two or more low-reflection patterns have a width of 3 μm to 5 μm in a plan view.

14. The display apparatus of claim 2, each of the two or more low-reflection patterns are disposed to be spaced apart from each other at intervals of 5 μm or more.

15. The display apparatus of claim 1, further including:
a reference line extending in a first direction and a reference voltage applied thereto; and
a data line extending in the first direction and a data voltage applied thereto; and
wherein the low reflection layer is electrically connected to the reference line.

16. The display apparatus of claim 15, wherein the low-reflection layer is disposed to be spaced apart from the data line.

17. The display apparatus of claim 1, wherein the low-reflective layer has a mesh shape in a plan view.

18. The display apparatus of claim 7, wherein the low refractive layer includes a material having a first refractive index and the high refractive layer includes a material having a second refractive index, and
wherein the second refractive index is different from the first refractive index.

19. The display apparatus of claim 18, wherein the difference between the first refractive index and the second refractive index is 0.05 to 0.40.
